(19) United States
(12) Patent Application Publication
(10) Pub. No.: US 2011/0226299 A1
(43) Pub. Date: Sep. 22, 2011

(54) DEVICE FOR ENERGY CONVERSION, ELECTRICAL SWITCHING, AND THERMAL SWITCHING

(76) Inventor: Tarek Makansi, Tucson, AZ (US)

(21) Appl. No.: 13/131,535

(22) PCT Filed: Dec. 31, 2009
(86) PCT No.: PCT/US09/69959

§ 371 Date: May 26, 2011

Related U.S. Application Data
(62) Division of application No. 61/204,212, filed on Jan. 2, 2009.

(51) Int. Cl. H01L 35/28

(52) U.S. Cl. 136/203; 136/205

(57) ABSTRACT

An improved design for maintaining nanometer separation between electrodes in tunneling, thermo-tunneling, diode, thermionic, thermoelectric, thermo-photovoltaic, current limiting, reset-able fusing, relay, circuit breaker and other devices is disclosed. At least one electrode is of a curved shape whose curvature is altered by temperature. Some embodiments use the nanometer separation to limit or stop current flow. Other embodiments reduce the thermal conduction between the two electrodes when compared to the prior art. The end result is an electronic device that maintains two closely spaced parallel electrodes in stable equilibrium with a nanometer gap there-between over a large area in a simple configuration for simplified manufacturability and use to convert heat to electricity or electricity to cooling, or limit current flow, or interrupt current flow.

The present invention pertains to diode, thermionic, tunneling, current limiting, current interruption, and other devices that are designed to have very small spacing between electrodes and in some cases also require thermal isolation between electrodes. The invention has particular utility in connection with thermo-tunneling generators and heat pumps, and can be applied to similar systems using thermionic and thermoelectric methods, and will be described in connection with such utility, although other utilities are also contemplated. These thermo-tunneling generators and heat pumps convert thermal energy into electrical energy and can operate in reverse to provide refrigeration. The invention also may be applied to any device that requires close, parallel spacing of two electrodes with a voltage applied or generated between them. The invention also may be applied to a switching device, such as a current limiter, over-temperature protector, relay, reset-able fuse, or circuit breaker, in which the electrical behavior is highly dependent on temperature or parameters that can affect temperature of an electrode such as current, voltage, or a nearby heat source. The invention also may be applied as a thermal switch whose thermal conduction may be varied or programmed.

The phenomenon of high-energy electron flow from one conductor (emitter) to another conductor (collector) has been used in many electronic devices and for a variety of purposes. For example, vacuum-tube diodes were implemented this way, and the physical phenomenon was called thermionic emission. Because of the limitations imposed by the relatively large physical spacing available, these diodes needed to operate at a very high temperature (greater than 1000 degrees Kelvin). The hot electrode needed to be very hot for the electrons to gain enough energy to travel the large distance to the collector and overcome the high quantum barrier. Nevertheless, the vacuum tube permitted electronic diodes and later amplifiers to be built. Over time, these devices were optimized, by using alkali metals, like cesium, or oxides to coat the electrodes, in an effort to reduce the operating temperature. Although the temperatures for thermionic generation are still much higher than room temperature, this method of power generation has utility for conversion of heat from combustion, from solar concentrators, or other sources to electricity.

Later, it was discovered that if the emitter and the collector were very close to each other, on the order of atomic distances like 2 to 20 nanometers, then the electrons could flow at much lower temperatures, even at room temperature. At this small spacing, the electron clouds of the atoms of the two electrodes are so close that hot electrons actually flow from the emitter cloud to the collector cloud without physical conduction. This type of current flow when the electron clouds are intersecting, but the electrodes are not physically touching, is called tunneling. The scanning tunneling microscope, for example, uses a pointed, conducting stylus that is brought very close to a conducting surface, and the atomic contours of this surface can be mapped out by plotting the electrical current flow as the stylus is scanned across the surface. U.S. Pat. No. 4,343,993 (Binnig, et al.) teaches such a method applied to scanning tunneling microscopy.

It has been known in the industry that if such atomic separations could be maintained over a large area (one square centimeter or even one square millimeter, for example), then a significant amount of heat could be converted to electricity by a single diode-like device and these devices would have utility as refrigerators or in recovering wasted heat energy from a variety of sources. See Efficiency of Refrigeration using Thermotunneling and Thermionic Emission in a Vacuum: Use of Nanometer Scale Design, by Y. Hishinuna, T. H. Geballe, B. Y. Moyzhes, and T. W. Kenny, Applied Physics Letters, Volume 78, No. 17, 23 Apr. 2001; Vacuum Thermionic Refrigeration with a Semiconductor Heterojunction Structure, by Y. Hishinuna, T. H. Geballe, B. Y. Moyzhes, Applied Physics Letters, Volume 81, No. 22, 25 Nov. 2002; and Measurements of Cooling by Room Temperature Thermionic Emission Across a Nanometer Gap, by Y. Hishinuma, T. H. Geballe, B. Y. Moyzhes, and T. W. Kenny, Journal of Applied Physics, Volume 94, No. 7, 1 Oct. 2003. The spacing between the electrodes must be small enough to allow the “hot” electrons (those electrons with energy above the Fermi level) to flow, but not so close as to allow normal conduction (flow of electrons at or below the Fermi level). In some cases, the vacuum gap might be used to minimize thermal conductance by lattice phonon vibration and the filtering of the hot electrons can take place in a semiconductor or thermoelectric material adjacent to the gap as exemplified in International PCT PCT/US07/77042 by the same inventor. There is a workable range of separation distance between 0.5 and 20 nanometers that allows thousands of watts per square centimeter of conversion from electricity to refrigeration. See Efficiency of Refrigeration using Thermotunneling and Thermionic Emission in a Vacuum: Use of Nanometer Scale Design, by Y. Hishinuna, T. H. Geballe, B. Y. Moyzhes, and T. W. Kenny, Applied Physics Letters, Volume 78, No. 17, 23 Apr. 2001. These references also suggest the advantage of a coating or monolayer of an alkali metal, or other material, on the emitting electrode in order to achieve a low work function in the transfer of electrons from one electrode to the other. This coating or monolayer further reduces the operating temperature and increases the efficiency of conversion for those configurations without a separate means for electron filtering.

Mahan showed that the theoretical efficiency of a thermionic refrigerator, using electrodes with a work function of 0.7 eV and a cold temperature of 500 K. is higher than 80% of Carnot efficiency. See Thermionic Refrigeration, By G. D. Mahan. Journal of Applied Physics, Volume 76, No. 7, 1 Oct. 1994. Also, see Multilayer Thermionic Refrigerator, By G. D. Mahan, J. A. Sofao and M. Bartkoiwak, Journal of Applied Physics, Volume 83, No. 9, 1 May 1998. By analogy a conversion efficiency of the electron tunneling process is expected to also be a high fraction of Carnot efficiency. Carnot efficiency presents an upper bound on the achievable efficiency of thermal energy conversion.

The maintenance of separation of the electrodes at atomic dimensions over a large area has been the single, most significant challenge in building devices that can remove heat from a conductor. The scanning tunneling microscope, for example, requires a special lab environment that is vibration free, and its operation is limited to an area of a few square nanometers. Measurements of cooling in a working apparatus have been limited to an area of a few square nanometers. See Measurements of Cooling by Room Temperature Thermionic Emission Across a Nanometer Gap, by Y. Hishinuma, T. H. Geballe, B. Y. Moyzhes, and T. W. Kenny, Journal of Applied Physics, Volume 94, No. 7, 1 Oct. 2003.

In my earlier, in PCT/US07/77042, I describe devices that achieve much larger amounts of energy conversion of milliwatts or fractions of watt using a pair of bimetal electrodes tested in a vacuum chamber. Devices described in my aforesaid patent application, have been used successfully to form nanometer gaps in a bell jar vacuum apparatus such that many materials on either side of the gap can be explored and measured. In addition, a fully packaged device with the successful gap-forming method of my aforesaid PCT/US07/77042 will be presented here, and this device can serve as a fully functional energy conversion product usable outside of a vacuum apparatus. See also my earlier filed PCT/US09/33660 which describes methods of forming gaps, achieving large amounts of heat transfer, and refined methods for packaging such a device.

Hence, there remains a need for a fully packaged device, which cost-effectively and efficiently converts heat energy into electrical energy in a package that is convenient to use for both the heat source as input and the electrical circuits needing power as output. Abundant sources of heat, including waste heat, could easily become sources of electricity. Examples where employing such devices would help the environment, save money, or both, include:

(1) Conversion of the sun's heat and light into electricity more cost effectively than photovoltaic devices currently used.

(2) Recovery of the heat generated by an internal combustion engine, like that used in automobile, back into useful motion. Some automobiles available today, called hybrid gas-electric automobiles, can use either electrical power or internal combustion to create motion. About 75% of the energy in gasoline is converted to waste heat in today's internal combustion engine. A tunneling conversion device could recover much of that heat energy from the engine of a hybrid automobile and put it into the battery for later use. U.S. Pat. No. 6,651,760 (Cox, et al.) teaches a method of converting the heat from a combustion chamber and storing or converting the energy to motion.

(3) Reducing the need for noxious gases to enter the atmosphere. The more energy-efficient hybrid automobile is a clear example where noxious exhaust gases escaping into the atmosphere can be reduced. A device that converts engine and exhaust heat of the hybrid engine and then stores or produces electricity in the hybrid battery would further increase the efficiency of the hybrid automobile and reduce the need to expel noxious gases. Coolants used in refrigeration are other examples of noxious gases that are necessary to remove heat, and tunneling conversion devices could reduce the need for emission of noxious gases.

(4) Recovery of heat energy at a time when it is available, then storing it as chemical energy in a battery, and then re-using it at a time when it is not available. Tunneling conversion devices could convert the sun's energy to electricity during the day and then store it in a battery. During the night, the stored battery power could be used to produce electricity.

(5) Power generation from geothermal energy. Heat exists in many places on the surface of the earth, and is virtually infinitely abundant deep inside the earth. An efficient tunneling conversion device could tap this supply of energy.

(6) Production of refrigeration by compact, silent and stationary solid state devices, where such a tunneling device could provide cooling for air conditioners or refrigeration to replace the need for bulky pneumatic machinery and compressors.

(7) Power generation from body heat. The human body generates about 100 watts of heat, and this heat can be converted to useful electrical power for handheld products like cell phones, cordless phones, music players, personal digital assistants, and flashlights. A thermal conversion device as presented in this disclosure can generate sufficient power to operate or charge the batteries for these handheld products from heat applied through partial contact with the body.

(8) Electrical power from burning fuel. A wood stove generates tens of thousands of watts of heat. Such a tunneling device could generate one or two kilowatts from that heat which is enough to power a typical home's electric appliances. Similar applications are possible by burning other fuels such as natural gas, coal, and others. Then homes in remote areas may not require connection to the power grid or noisy electrical generators to have modern conveniences.

(9) Electrical switching or current limiting in response to heat or temperature. Because these devices adjust the spacing of the nanometer gap based on temperature of an electrode, these devices may be deployed to open or limit current flow across into a circuit in response to a temperature that is reached by the current flow through the device or from the heat from another device, possibly one that is in danger of overheating due to a faulty event. The devices disclosed here operating as a relay or circuit breaker have the advantage of much smaller size due to the protection of the contact material within a vacuum enclosure, and also the ability to limit current by providing a nanometer gap that is not prone to arcing or other damage that is typical of open-air environments.

The challenge in bringing two parallel electrodes together within less than 20.0 nanometer separation gap and the proposed solution by this inventor and others is well described in my earlier filed PCT/US07/77042 and PCT/US09/33660, and in “Analysis of nanometer vacuum gap formation in thermo-tunneling devices”, by E T Enikov and T Makansi, Nanotechnology Journal, 2008. Here, we will focus on a fully packaged device with its own vacuum chamber that can be manufactured at a low cost for mass production and competitively priced relative to compressors. turbines, and electrical generators. This device contains within it the gap-forming bimetal electrode design described in my aforesaid PCT/US07/77042 and PCT/US09/33660.

The art of separating two conductors by about 1.0 to 20.0 nanometers over a large area has been advanced by the use of an array of feedback control systems that are very precise over these distances. A control system includes a feedback means for measuring the actual separation, comparing that to the desired separation, and then a moving means for bringing the elements either closer or further away in order to maintain the desired separation. The feedback means can measure the capacitance between the two electrodes, which increases as the separation is reduced. The moving means for these dimensions is, in the state of the art, an actuator that produces motion through piezoelectric, magnetostriction, or electrostriction phenomena. U.S. Pat. No. 6,720,704 (Tavkhelidze, et al.) and U.S. Pat. No. 7,253,549 (Tavkhelidze, et al.) and US Patent Application No. 2007/0033782 (Taliashvili et al.) describes such a design that includes shaping one surface using the other and then using feedback control systems to finalize the parallelism prior to use. Because of the elaborate processes involved in shaping one surface against the other and the use of multiple feedback control systems to maintain parallelism, this design approach is a challenge to manufacture at a low cost.

Other methods have been documented in U.S. Pat. No. 6,774,003 (Tavkhelidze, et al.), and U.S. Pat. No. 7,140,102 (Taliashvili, et al.), and US Patent Applications 2002/0170172 (Tavkhelidze, et al.), 2006/0038290 (Tavkhelidze, et al.), and 2001/0046749 (Tavkhelidze, et al.) that involve the insertion of a “sacrificial layer” between the electrodes during fabrication. The sacrificial layer is then evaporated to produce a gap between the electrodes that is close to the desired spacing of 1 to 20 nanometers. These three methods are either susceptible to post-fabrication fluctuations due to warping or thermal expansion differences between the electrodes, or require the array of actuators to compensate for these fluctuations, as described in US Patent Application Nos. 2005/0189871 (Tavkhelidze, et al.) and 2007/0056623 (Tavkhelidze, et al.).

Another method of achieving and maintaining the desired spacing over time is documented in U.S. Pat. No. 6,876,123 (Martinovsky, et al.) and U.S. Pat. No. 7,305,839 (Weaver) and U.S. Pat. No. 6,946,596 (Kucherov, et al.) in US Patent Application Nos. 2004/0050415, 2006/0192196 (Tavkhelidze, et al.), 2003/0042819 (Martinovsky, et al.), 2006/0207643 (Weaver et al.), 2007/0069357 (Weaver et al.), and 2008/0042163 (Weaver) through the use of dielectric spacers that hold the spacing of a flexible electrode much like the way poles hold up a tent. One disadvantage of these dielectric spacers is that they conduct heat from one electrode to the other, reducing the efficiency of the conversion process. Another disadvantage of this method is that the flexible electrodes can stretch or deform between the spacers over time in the presence of the large electrostatic forces and migrate slowly toward a spacing that permits conduction rather than tunneling or thermionic emission. Some of the challenges of forming a nanometer gap with these methods is summarized in “Thermotunneling Based Cooling Systems for High Efficiency Buildings”, by Marco Aimi, Mehmet Arik, James Bray, Thomas Gorczyca, Darryl Michael, and Stan Weaver, General Electric Global Research Center, DOE Report Identifier DE-FC26-04NT42324, 2007.

Another method for achieving a desired vacuum spacing between electrodes is reveled in US Patent Application Nos. 2004/0195934 (Tanielian), 2006/0162761 (Tanielian), 2007/0023077 (Tanielian), 2007/0137687 (Tanielian), and 2008/0155981 (Tanielian) wherein small voids are created at the interface of two bonded wafers. These voids are small enough to allow thermo-tunneling of electrons across a gap of a few nanometers. Although these gaps can support thermo-tunneling, unwanted thermal conduction takes place around the gaps, and the uniformity of the electrode spacing is difficult to control.

Yet another method for achieving a thermo-tunneling gap is by having the facing surfaces of two wafers be in contact, then using actuators to pull them apart by a few nanometers, as described in U.S. Patent Application 2006/0000226 (Weaver). Although this method can produce a thermo-tunneling gap, this method suffers from the cost of multiple actuators and the thermal conduction between wafers outside of the gap area.

The present disclosure provides improvements in the packaging, fabrication, and more specific implementation detail of the gap-forming designs described in my aforesaid PCT/US07/77042 and PCT/US09/33660. Two new methods for fabricating the chip pair and three new methods for enclosing the chip pairs into vacuum packages are disclosed here.

The two new chip fabrication methods address two limitations of the prior art. One new method allows for a deposited thermoelectric film to be annealed and polished at a wafer level prior to slicing of the wafer into individual chips. The other new method allows for single-crystal or polycrystalline wafers to be thinned down and polished and then used as thermoelectric layers. Many previous articles describe the surface roughness introduced by annealing a deposited thermoelectric film, such as “The thermoelectric properties and crystallography of Bi—Sb—Te—Se thin films grown by ion beam sputtering”, by H. Noro, K. Sato, and H. Kagechika, Journal of Applied Physics, 73(3) 1 Feb. 1993. In addition, many articles claim that single crystals offer higher thermoelectric performance than similar materials in polycrystalline or amorphous form, such as Thermal and electrical properties of Czochralski grown GeSi single crystals, by I. Yonenaga et. al. Journal of Physics and Chemistry of Solids 2001.

In addition, three new package design approaches are presented, each trading off cost and reliability uniquely. The first and preferred package design uses an individual vacuum tube for each gap-forming chip pair. The second package design Allows for multiple gap-forming chip pairs to be housed in a single vacuum cavity. The third package design creates the vacuum cavities on the same wafers that are used to fabricate the chip pairs.

A surface roughness of less than 1.0 nanometer can be achieved by any of several techniques known to the industry. Even though silicon and glass wafers are routinely polished to sub-nanometer roughness, the deposition of metal films creates additional roughness from nucleation and grain formation. This surface roughness can then be removed by (1) using a post-polishing process such as chemical mechanical polish called CMP, (2) cooling the substrate during deposition to prevent or minimize grain formation, or (3) pressing the surface against a known smooth surface such as that of a raw wafer. These and other polishing techniques are readily available in the industry for achieving less than 1.0 nanometers surface roughness on metals, semiconductors, and other materials. In all of these cases for achieving a smooth surface, the fabrication equipment and processing art readily available in the industry indicate a strong preference of smoothing the surface of an entire wafer vs. at a chip level. Methods disclosed here focus on wafer level smoothing integrated into the chip fabrication process.

Other systems, devices, features and advantages of the disclosed device and process will be or become apparent to one with skill in the art upon examination of the following drawings and detailed description. It is intended that all additional systems, devices, features, and advantages be included within this description, be within the scope of the present invention, and be protected by the accompanying claims.

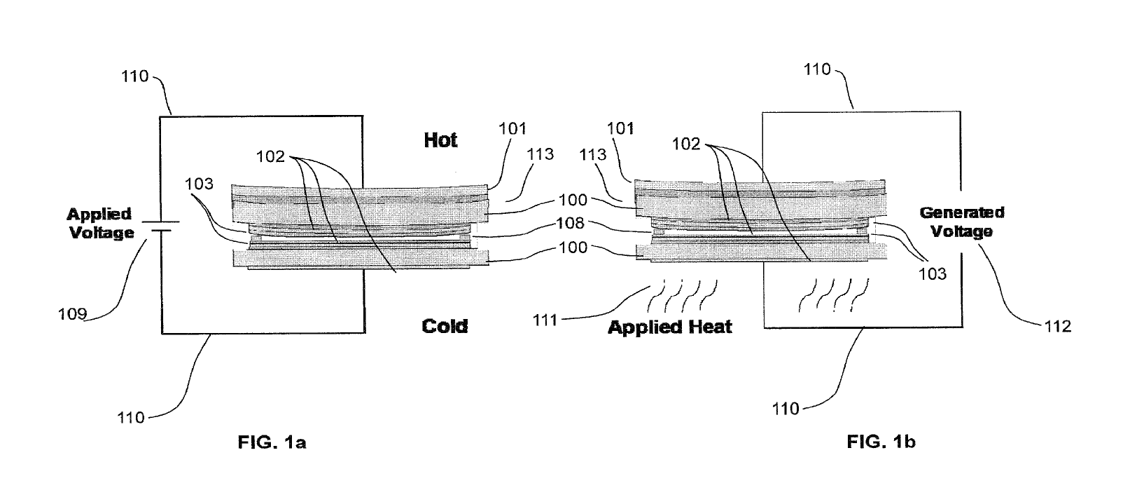

Many aspects of the disclosed device and process can be better understood with reference to the attached drawings FIGS. 1-10. The components in the drawings are not necessarily to scale, emphasis instead being placed upon clearly illustrating the principles of the present invention. Moreover, in the drawings, like reference numerals do not need corresponding parts throughout the several views. While exemplary embodiments are disclosed in connection with the drawings, there is no intent to limit the disclosure to the embodiments disclosed herein. On the contrary the intent is to cover all alternatives, modifications and equivalents.

FIG. 1a and FIG. 1b illustrate a single junction of the present invention with one curved electrode and one flat electrode with glass posts on the corners. FIG. 1a shows how this chip pair may be utilized for cooling or refrigeration. FIG. 1b shows how this same chip pair may be utilized for conversion of heat to electricity or for current limiting or for current interruption in response to temperature;

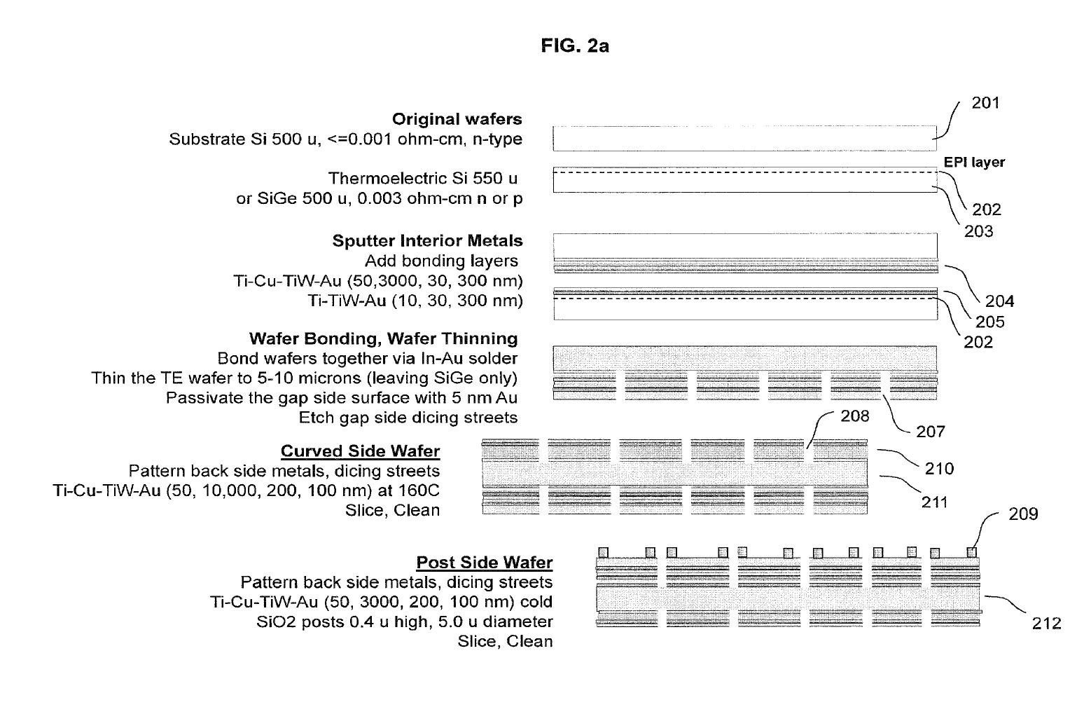

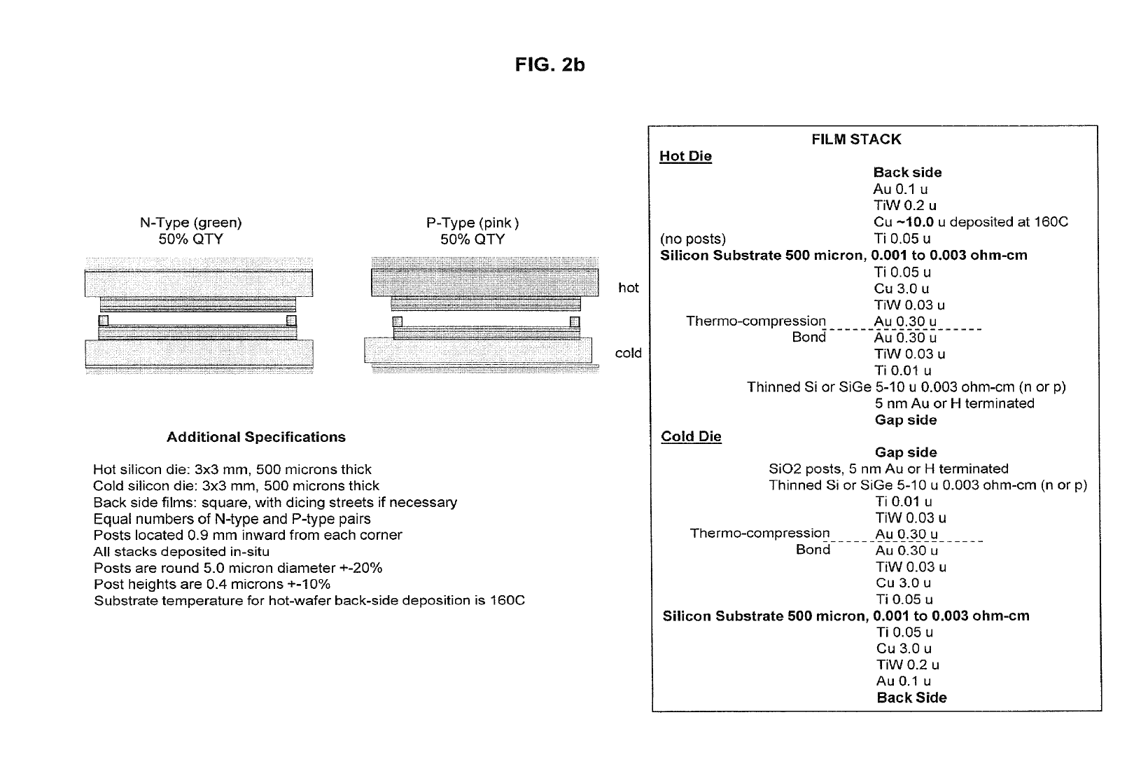

FIG. 2a and FIG. 2b illustrate an example process for fabricating the chip pair of FIG. 1 wherein the active thermoelectric layer is a single-crystal or other crystallized material that is available to this process in the form of a wafer. FIG. 2a shows the sequence of processing to arrive at the chip pair illustrated in FIG. 2b;

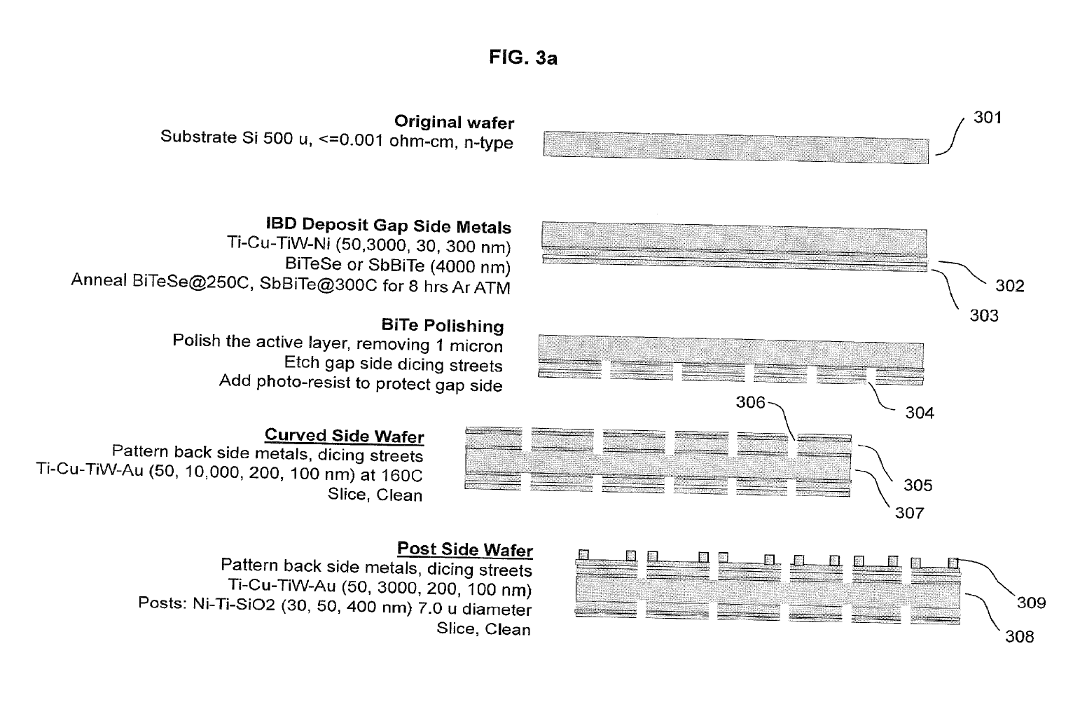

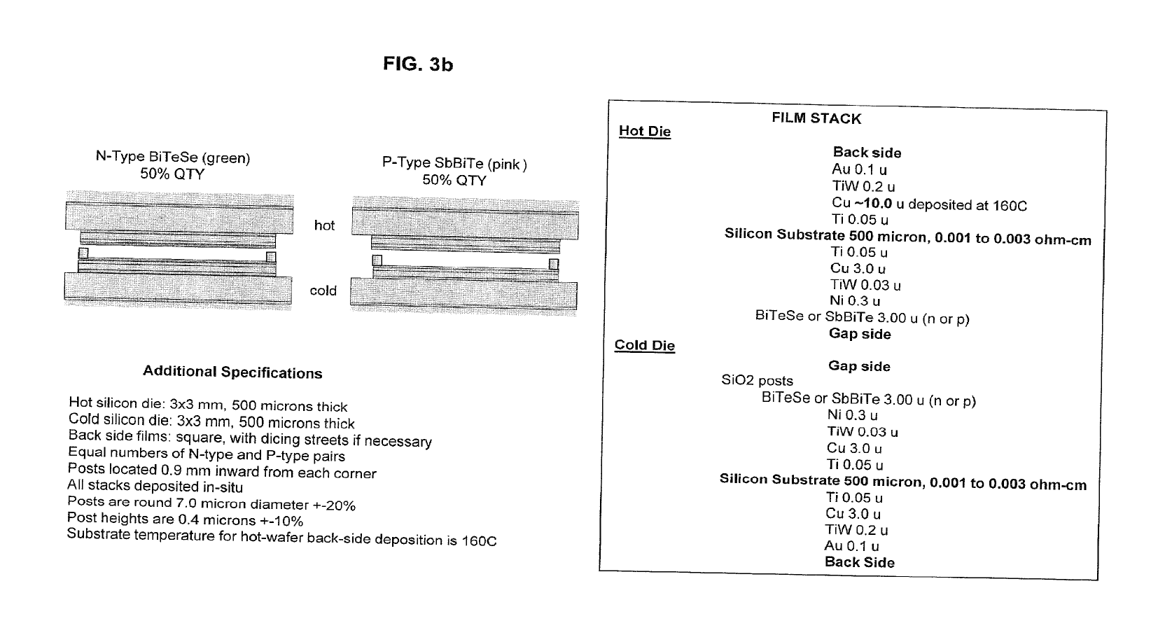

FIGS. 3a and 3b illustrate an example process for fabricating the chip pair of FIG. 1 wherein the active thermoelectric layer is deposited as an amorphous film, then annealed and polished at the wafer level. FIG. 3a illustrates the sequence of processing to arrive at the chip pair illustrated in FIG. 3b;

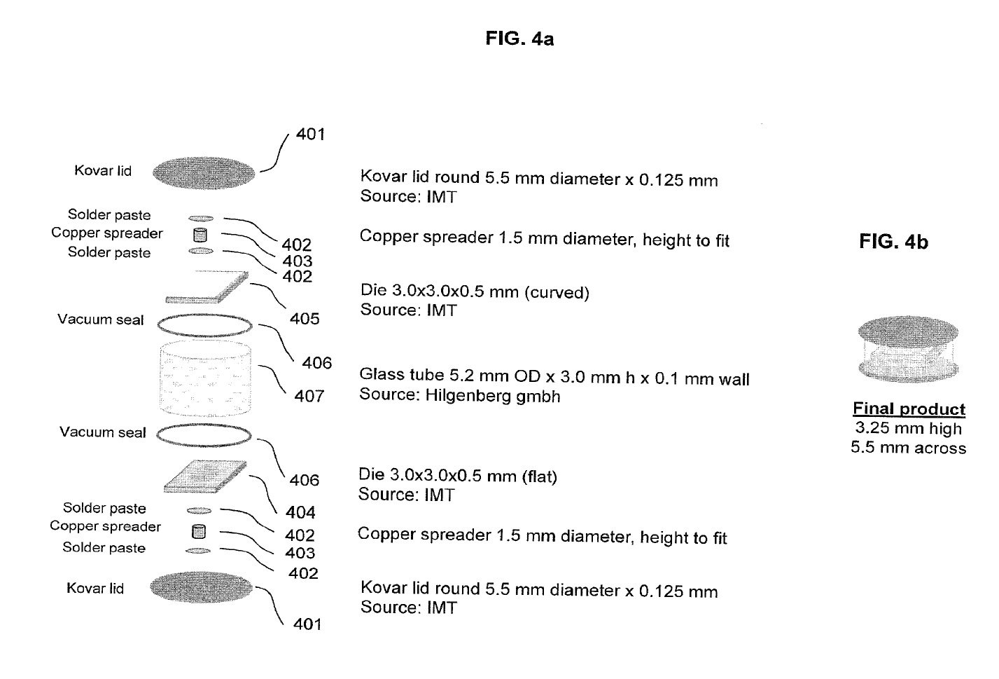

FIGS. 4a and 4b illustrate how the chip pairs of FIG. 1, 2 or 3 may be packaged into a vacuum chamber with a cylindrical glass wall and metal top and bottom. FIG. 4a shows how these and other parts are stacked up to achieve the finished product shown in FIG. 4b;

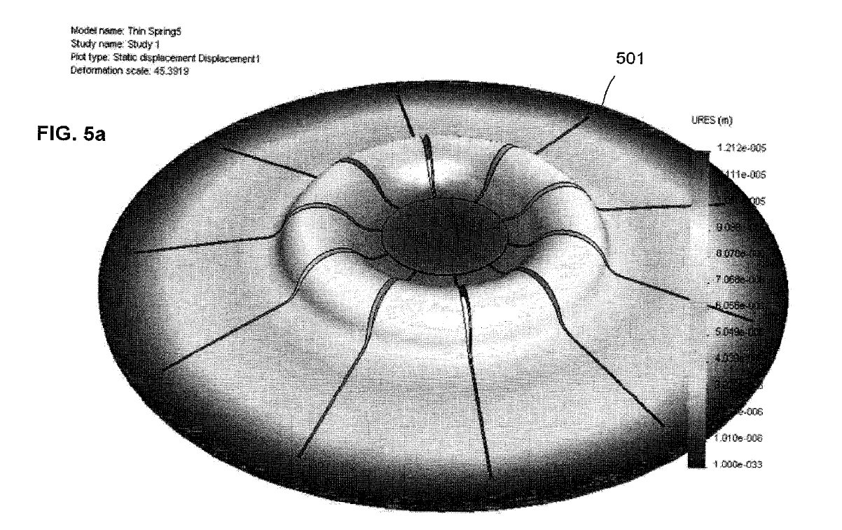

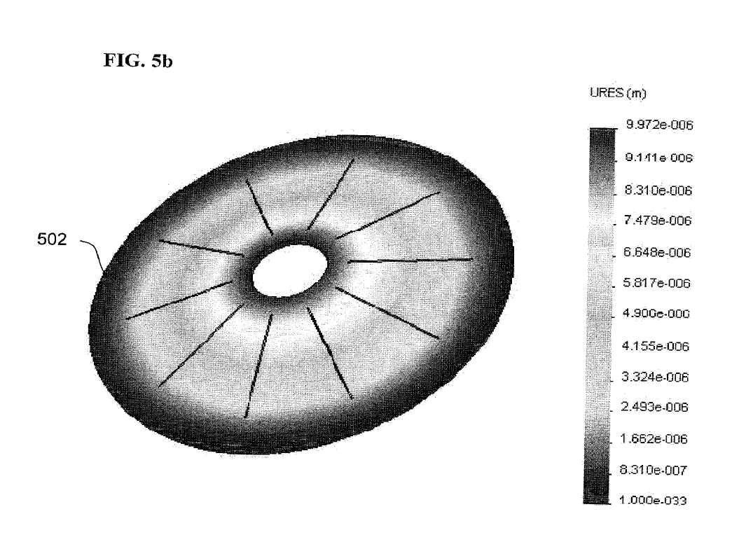

FIGS. 5a, 5b, and 5c illustrate three sample designs of a spring that could be added to the stack of FIG. 4b in order to provide a needed spring force holding the two chips in the chip pair together while still permitting gap formation. This spring is designed such that heat flows from the center to the perimeter, and the design maximizes thermal conduction and electrical conduction while maintaining the compliance needed for gap formation;

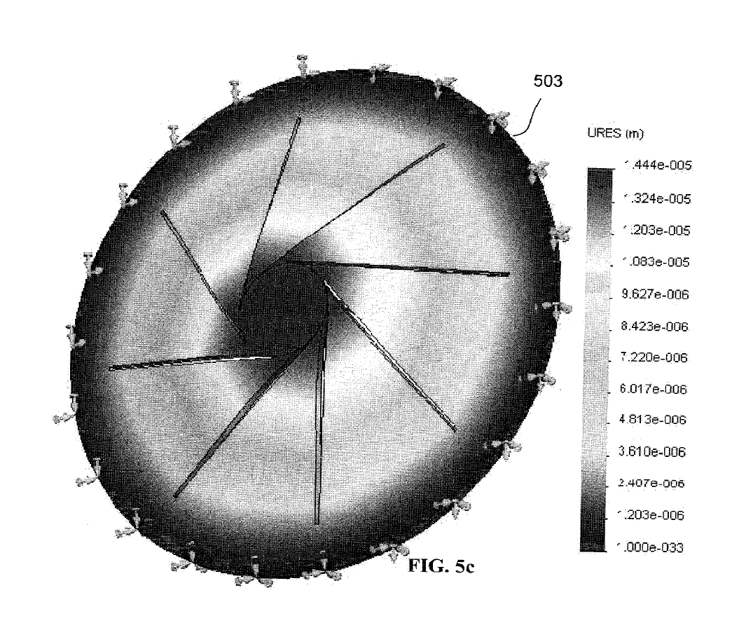

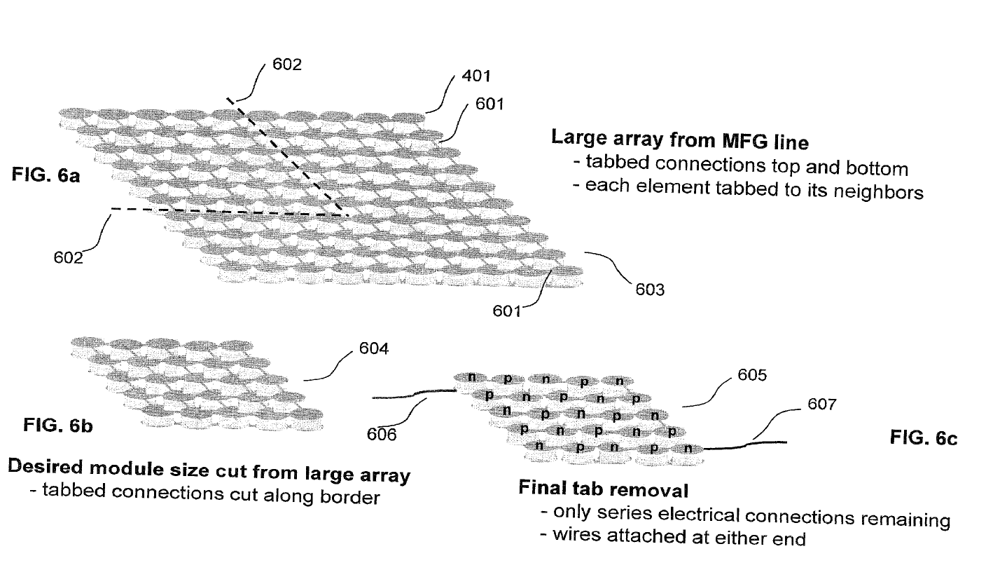

FIGS. 6a-6c show how multiples of the devices of FIG. 4b could be fabricated together and simultaneously provides the series or parallel electrical connections linking one package to a neighboring one;

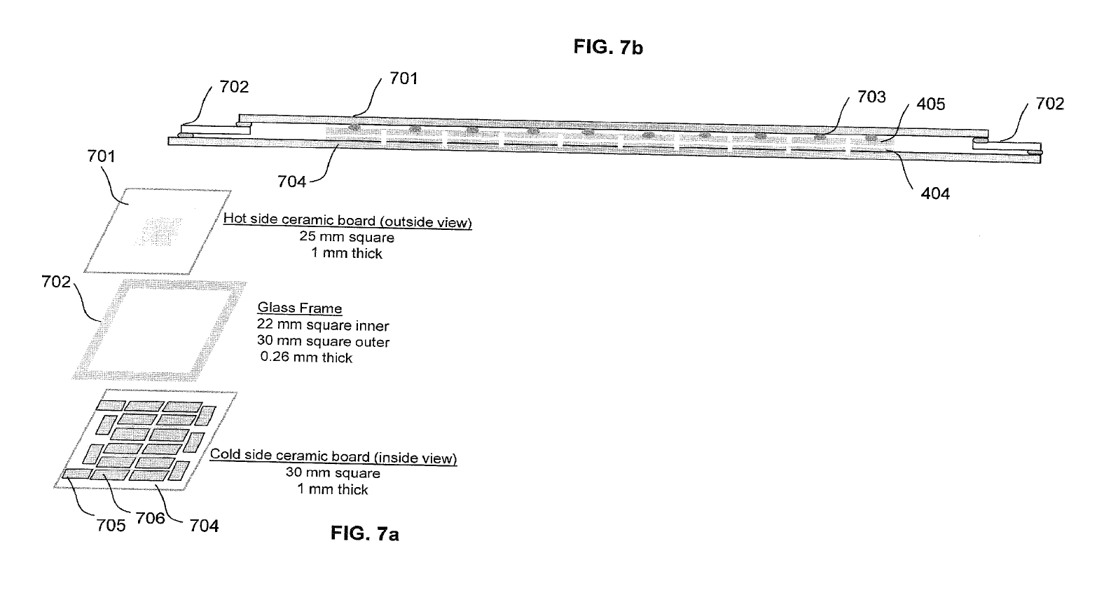

FIGS. 7a and 7b show another method for packaging many chip pairs as shown in FIGS. 1a, b, 2a, b, or 3a,b together into one vacuum cavity, reducing the number and handling of individual parts. FIG. 7a shows the top, bottom, and walls of the vacuum cavity, and FIG. 7b shows how the chip pairs are mounted inside the cavity;

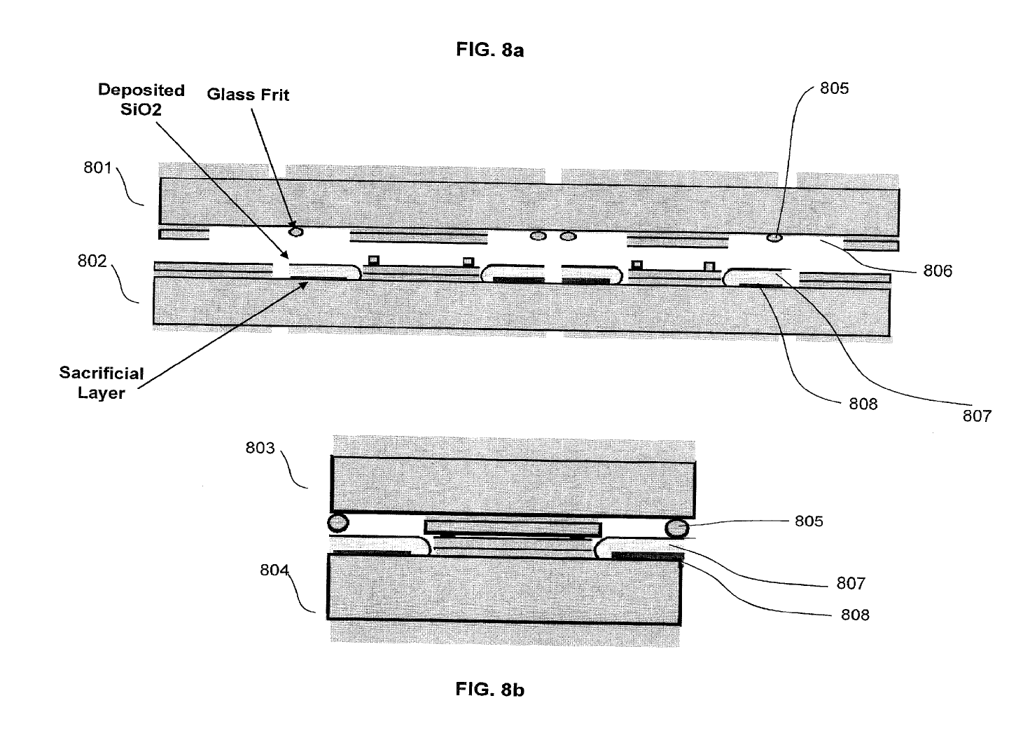

FIGS. 8a and 8b show a method of fabricating the vacuum package on the same wafers that are used to fabricate the chip pairs. Instead of a separate part used for the glass wall as in FIG. 4b and FIG. 7b, the glass wall for an individual chip pair is deposited on one wafer and bonded to the other wafer;

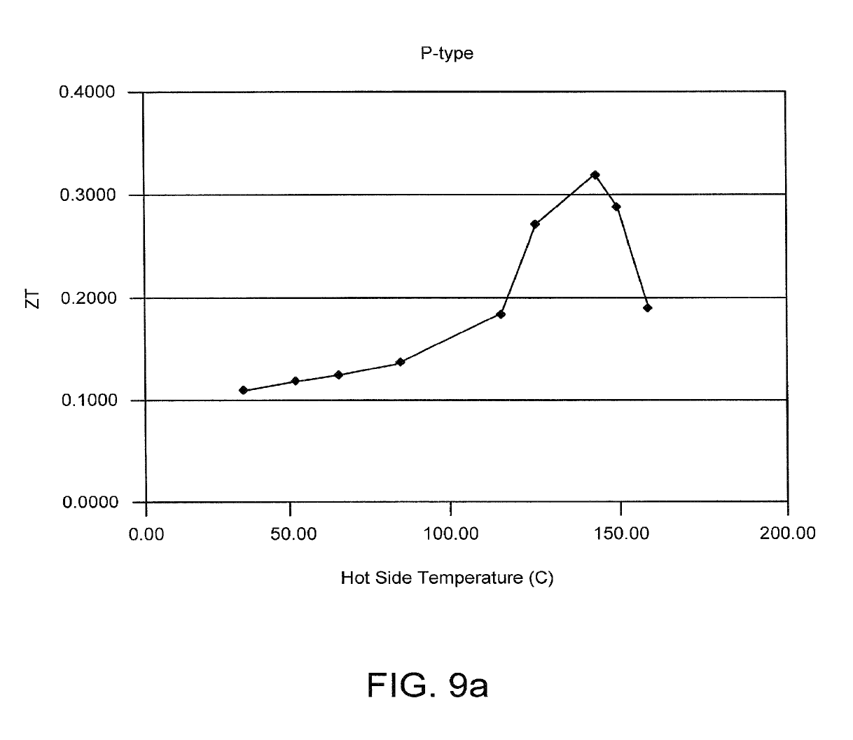

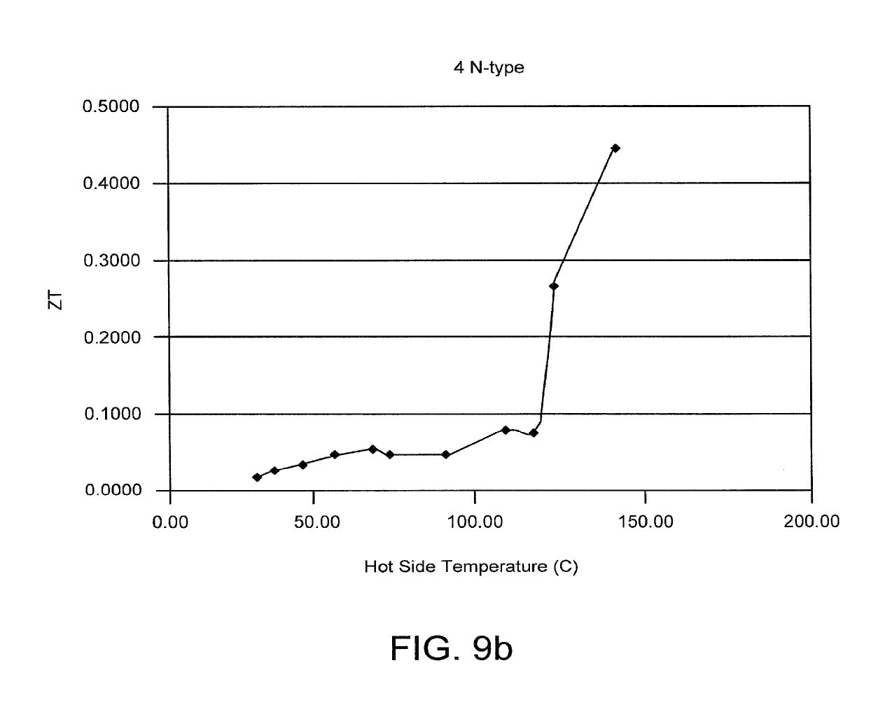

FIGS. 9a and 9b show the thermoelectric performance, as measured by industry-standard figure of merit ZT, of devices fabricated per this invention. FIG. 9a shows how the ZT of a p-type device increases as a gap is formed. FIG. 9b shows how the ZT of an n-type device increases as a gap is formed.

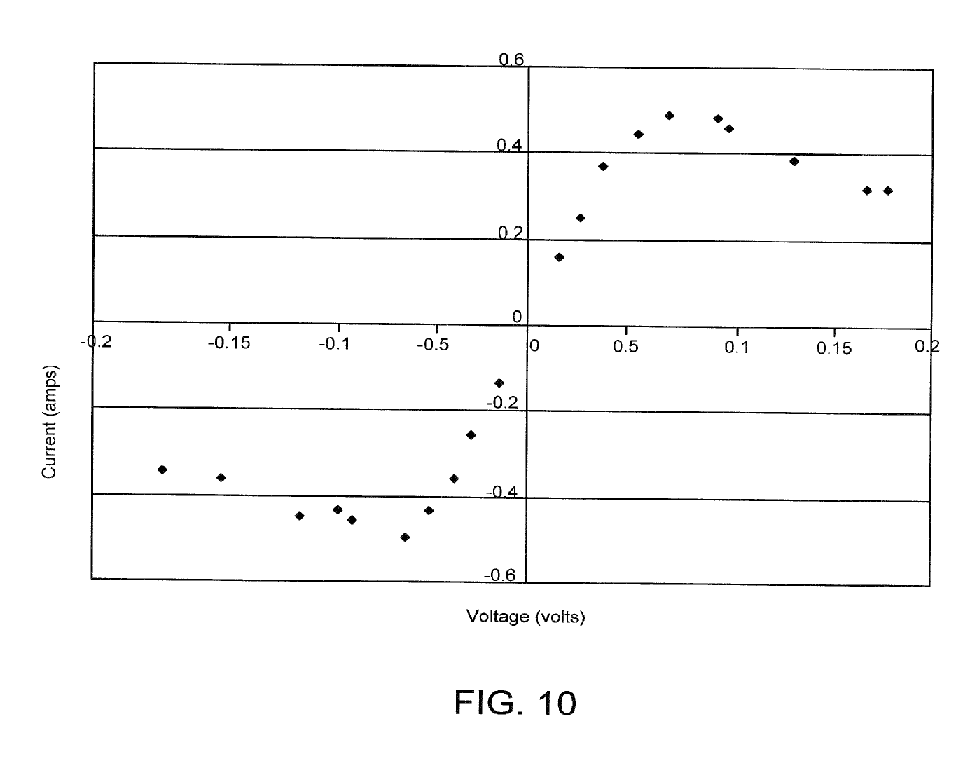

FIG. 10 shows the current vs. voltage behavior of a device fabricated as described in this invention with a metal layer substituting for the thermoelectric layer. The current-voltage behavior exhibited is similar to the current limiting and reset-able fuse behavior of other devices used in the power electronics industry.

Referring more specifically to the drawings in which like reference numerals refer to like elements throughout the several views, exemplary embodiments of the device and process of the present disclosure are illustrated in the several drawing figures.

In FIG. 1a, two electrodes are shown, one curved and the other essentially flat. A piece of single-crystal silicon 100 serves as the substrate, and this substrate is highly doped to levels of 0.001 to 0.01 ohm-cm to allow electrical conductivity from top to bottom. Without limitation, other metals or semiconductors could be used for substrate 100 such as silicon carbide, germanium, gallium arsenide, and low thermal expansion metal alloys such as Kovar. Metal layers 101 and 102 on either side of the silicon substrate 100 serve to spread the electrical current allowing this current to flow across the entire area of the silicon substrate 100, thereby reducing resistance of current flow from the top of each substrate to the bottom. Metal layer 101 on the top of the upper substrate is thicker, or laterally larger, or deposited or otherwise adhered at a higher temperature, or any combination of these, than other metal layers 102 on the substrates 100. Innermost layer 103 is the thermoelectrically active material. Depositing metal layer 101 on or otherwise adhering it to silicon substrate 100 at an elevated temperature forms the curved upper electrode. As the pair of layers 100 and 101 cool down to room temperature after deposition or adhesion, the greater thermal contraction of metal 101 relative to silicon 100 introduces mechanical stresses that give rise the curved shape shown. This curvature occurs in both lateral dimensions, making the curved shape a dome, although FIG. 1a and FIG. 1b show only a profile view. Without limitation, other arrangements for achieving a curved surface are included such as micro-machining or pulling forces of an interior vacuum cavity.

In operation, the two electrodes in FIG. 1a and FIG. 1b are spring loaded to push against each other, and the apparatus in this figure is placed in a vacuum chamber. To activate the device for cooling as illustrated in FIG. 1a, a voltage 109 is applied between the very top 101 and very bottom 102 metal layers through wires 110. This voltage gives rise to a current flow through the thermoelectrically active layer 103 and this current moves heat either in the same direction of the current if the material 103 is p-type or in the opposite direction as the current if material 103 is n-type material.

The thermoelectric material 103 in the preferred embodiment is Bismuth Telluride Bi₂Te₃ or alloyed derivatives thereof. Without limitation, other or more complex thermoelectric materials may substitute for Bi₂Te₃. A feature of my invention is that the nanometer gap reduces the thermal conduction from the hot to the cold side, thereby making the performance of the device much less dependent on special materials as in the prior art. One example of a complex thermoelectric material is a super-lattice, which is a thermoelectric film comprised of multiple very thin films, the borders of which reduce the lattice thermal conduction. Other examples of complex thermoelectric materials include clathrates and chalcogenides. A comprehensive review of complex thermoelectric materials is provided in Complex Thermoelectric Materials, by G. Jeffrey Snyder and Eric S. Toberer, Nature Materials, Vol. 7, February 2008. Including those materials that have large or larger lattice thermal conductivity can enlarge the space of candidate materials for the invention device. These new material possibilities are important for many reasons. Elements in the periodic table with low lattice thermal conductivity are those with relatively large atomic weights. Semiconductors and metals with relatively large atomic weights tend have undesirable properties including: (1) toxicity, (2) radioactive, (3) high cost, (4) scarcity in either natural or man-made forms, and/or (5) inability to withstand higher temperatures. For example, toxicity is a major concern for traditional thermoelectric materials. Tellurium and similar elements like Antimony that are used in traditional devices are toxic. Silicon and Germanium are semiconductors that are non-toxic, plentiful, and inexpensive. Silicon and Germanium are not used in traditional thermoelectric devices, however, because their lattice thermal conductivities are several times higher than Tellurium and Antimony. Silicon and Germanium would work just fine in the embodiment of FIG. 1a and FIG. 1b because lattice thermal conduction is minimized by the vacuum gap.

Also, in order for thermoelectric devices to be used in power generation, it is preferred to operate them at high temperatures. The laws of thermodynamics state that the higher the temperature delta in an engine, the higher the efficiency of that engine. Very high temperatures, approaching 1000 Kelvin are required to maintain high efficiency power generators, and these temperatures are routinely used in power plant engines fueled by coal, gas, or nuclear energy. Thermoelectric devices need to sustain these same temperatures in order to compete with existing power plants. Bismuth, Tellurium, and Antimony have melting points of 544K, 723K, and 904K respectively. Because of these low melting points, the operational temperature of traditional thermoelectric devices has been limited to 500K. If the hot side of the device is 500K and the cold side is cooled to room temperature. or 300K, then the theoretical maximum efficiency is 40%, and that assumes an infinite ZT. However, silicon and germanium have melting points of 1683K and 1211K, and hence can sustain the temperatures of up to 1000K required to compete with existing power plants in thermodynamic efficiency.

For details of thermoelectric performance of silicon-germanium, see Thermal and electrical properties of Czochralski grown GeSi single crystals, by I. Yonenaga et. al. Journal of Physics and Chemistry of Solids 2001. For details about the surface behavior of these materials, see “Selective Epitaxial Growth of SiGe on a SOI Substrate by Using Ultra-High-Vacuum Chemical Vapor Deposition”, by H. Choi. J. Bae, D. Soh, and S. Hong, Journal of the Korean Physical Society, Vol. 48, No. 4, April 2006, pp. 648-652 and “Strain relaxation of SiGe islands on compliant oxide”, by H. Yin et. al. Journal of Applied Physics, vol. 91, number 12, 15 June 2002.

To activate the device for power generation as illustrated in FIG. 1b, a heat source 111 is applied to the lower electrode, giving rise to a temperature gradient between the lower and upper electrodes and this gradient produces a voltage 112, called the Seebeck voltage, between the top and bottom electrodes. Dielectric separators 108 are located on each corner of the substrates to provide physical support with minimal thermal conduction from the hot side to the cold side. In the preferred embodiment, these separators are made of silicon dioxide. The height of separators 108 in FIG. 1a and FIG. 1b is selected such that as the upper electrode heats up, the thermal expansion differences the silicon and the metals cause the upper electrode to flatten, ultimately forming a gap in the center, as the corner separators become the supports.

The central portion of innermost thermoelectric layers 103 of the invention illustrated in FIG. 1a and FIG. 1b is similar to a traditional thermoelectric device with one unique exception, which is a feature of this invention. In a standard thermoelectric device, active layers 103 in central portion would be continuous from top to bottom. In the invention device, active layer 103 is interrupted by a gap of up to a few nanometers. This gap is short enough to allow electrons to tunnel across and move heat as in the prior art materials without a gap. The gap is also long enough to prevent the flow of phonons, or lattice vibrations, thereby reducing thermal conduction and increasing performance and efficiency.

Another advantage of the invention is the ability to operate over a range of temperatures. For traditional thermoelectric devices, Bi₂Te₃ and similar materials are used at low temperatures (lower lattice thermal conductivity, but lower melting points) and other materials like SiGe are used at higher temperatures (higher lattice thermal conductivity but higher melting points). The present invention allows a material such as SiGe to be used at the full range of temperatures because lattice thermal conduction is partially or totally eliminated by the vacuum gap illustrated in FIG. 1a and FIG. 1b.

Thermoelectric devices are generally reversible, meaning that a current flow through the device will produce refrigeration and, conversely, applying heat to one side will produce a voltage. The device of this invention is also reversible, and FIG. 1a and FIG. 1b show the preferred configuration for each of the two modes of operation. FIG. 1a shows the preferred configuration for refrigeration, and FIG. 1b shows the preferred configuration for power generation from heat.

In FIG. 1a, the curved bimetallic electrode 113 with the thick copper layer is the hot side. A voltage source 109 supplies a voltage to the top and bottom of the device through wires 110. This voltage produces a current flow through the thermoelectric material in the center of the device, and this current flow moves heat from the bottom electrode to the top electrode assuming that the thermoelectric material used is n-type. Without limitation, a similar diagram could be made with current flowing oppositely by reversing the applied voltage 109, and with a p-type material, the heat would still flow from the bottom electrode to the top electrode.

When the device of FIG. 1a is turned off, the voltage 109 is zero, and central contact exists between the two electrodes. The flow of current moves heat to the top electrode, increasing its temperature. This increased temperature causes the top electrode to flatten out which eventually creates a gap in the center and the top electrode now uses the corner separators 108 for support. The corner separators 108 might have a lubricating film, such as diamond like carbon (DLC) deposited either on the tops of the separators or on the facing surface 113 or both in order to facilitate micromovements and reduce the effects of friction. The gap in the center will increase in size until it reaches an equilibrium value. If a disturbance causes the gap to become larger than the equilibrium value, then less current will flow because the gap is opening the circuit between the two electrodes. Less current means less heat is moved to the upper electrode, lowering its temperature, and bending back toward the bottom electrode until the equilibrium is re-established. Conversely, if a disturbance causes the gap to be smaller than its equilibrium value, then more current will flow, moving more heat, increasing the temperature of the top electrode, and bending it away from the bottom electrode until again the equilibrium is re-established.

The device of FIG. 1a can be applied to thermoelectric cooling methods, also called the Peltier effect, by choosing active layer 103 to be a thermoelectrically sensitive material. Bismuth Telluride, Antimony Bismuth Telluride. Lead Telluride, Silicon Germanium, and many other materials are known to exhibit the thermoelectric effect, without limitation. In the case of thermoelectric methods applied to the device of FIG. 1a, the gap can be barrier-free, meaning that electrons do not need higher than average energy to traverse the gap. The quantum barrier of the bandgap of the thermoelectric material 103 already filters higher energy electrons which enables heat to be moved. So, in this case, the nanometer gap between the two active layers 103 merely needs to interrupt the lattice thermal conduction. The device of FIG. 1a also can be applied to thermo-tunneling cooling methods by choosing active layer 103 to be a low work function material. Examples of low work function materials are Cesium, Barium, Strontium and their oxides. The layer 103 could take the form of a monolayer, sub-monolayer, multiple monolayers, or deposited film. In the case of thermo-tunneling methods applied to the device of FIG. 1a, the gap length does introduce a barrier over which only higher energy electrons can traverse. In thermo-tunneling applications, the nanometer gap serves as both the quantum barrier to filter electrons and also as an interruption of the lattice thermal conduction.

In the preferred configuration for power generation in FIG. 1b, note that the curved, bimetallic electrode is now the cold side. Heat is applied to the flat electrode from a heat source 111. Because the temperature of the heat source might vary during operation, as in a concentrated solar application for example, it is preferable to apply the heat to the side that would not vary the gap from its optimal value. As is typical in thermoelectric devices, the heat source 111 creates a temperature gradient within the thermoelectrically sensitive material, which in turn creates a voltage that can be brought to an electrical circuit or storage unit needing power 112 through wires 110.

When no heat is applied at heat source 111, center contact exists between the two electrodes. As the heat source is turned on, some of this heat will flow through the center contact, increasing the temperature of the top electrode 113. The increased temperature causes the top electrode 113 to flatten out, ultimately creating a gap in the center as the top electrode then rests on the corner separators 108. As in the case for refrigeration, an equilibrium gap is formed. If a disturbance causes the gap to become larger than equilibrium, then the top electrode will cool down because of less heat traversing the gap, which causes the top electrode 113 to bend toward the bottom electrode, and re-establish the equilibrium. If a disturbance causes the gap to become smaller than equilibrium, then the increased heat conduction in the center will increase the temperature of the top electrode, causing it to bend away in the center until the equilibrium gap is re-established.

The device of FIG. 1b may be applied to thermoelectric power generation effects, also called the Seebeck effect, by choosing active layer material 103 to be a thermoelectrically sensitive material. Again, without limitation, the same materials mentioned earlier that exhibit the Peltier effect also exhibit the Seebeck effect. The device of FIG. 1b may also be applied to thermo-tunneling power generation by choosing the active layer 103 to be a low work function material. Without limitation, the same materials useful for thermo-tunneling cooling are also useful for thermo-tunneling power generation. The device of FIG. 1b may also be applied to thermo-photovoltaic methods by choosing lower active layer material 103 to be photo-emissive and the upper layer 103 to be photosensitive. Photo-emissive materials emit photons in response to the application of heat. Photosensitive materials generate electricity upon the receipt of photons. Photons are also capable of tunneling across a vacuum gap such as the one illustrated in FIG. 1b, thereby converting heat to electricity while retaining thermal isolation. The required gap length for photon tunneling is typically much less than the wavelength. For visible light, the wavelength is 400 to 700 nanometers, so a gap length of 1 nm to 200 nm is sufficiently small for effective photon tunneling. Without limitation, examples of photo-emissive materials are tungsten and titanium. Also without limitation, examples of photosensitive materials include photovoltaic materials such as silicon, germanium, tellurium, cadmium and combinations of these. For a summary of thermo-photovoltaic methods, see Micron-gap ThermoPhotoVoltaics (MTPV), by R. DiMatteo et al, Thermophotovoltaic Generation of Electricity, American Institute of Physics, 2004.

The devices illustrated in FIG. 1a and FIG. 1b also may be applied to electrical switching. In this case, the active layer 103 would be good conductor that can tolerate many cycles of contact and release without degradation. Gold is an example material that is used for this purpose, but without limitation, other metals and alloys could also be used such as gold-tin, gold-indium, gold-silver, and brass.

The device of FIG. 1b could be placed electrically in series between a power supply and an electrical load. Excessive current flow due to a fault in the load would heat up the electrodes in the device, and cause a gap to form in the center. This gap would then serve the purpose of limiting the current to safe level that prevents overheating or damage or a combination of overheating and damage. The device is operating as a reset-able fuse in this embodiment. One advantage of this fuse over conventional prior art fuses is that this invention device fully recovers once the fault is repaired and a replacement is not required as when a conventional fuse burns out.

Similarly, the heat source of the device of FIG. 1b could trigger the electrical opening of the device, thereby acting as a circuit breaker. The heat source could be a heating element that cuts off its own power supply when an over temperature situation occurs. The heat source could be the presence of a fire, smoke, or other dangerous high-temperature situation and the device could cut power or provide a logic signal to an alarm.

Without limitation, the devices of FIG. 1a and FIG. 1b may, in other embodiments, be arranged to provide the equivalent function of a reset-able fuse, circuit breaker, over-temperature protector, or simply as a high current switch with the electrical contacts protected in a vacuum chamber. In addition, the devices of FIG. 1a and FIG. 1b may provide the equivalent function as a relay, in which the relay is tripped by a providing electrical power to a heating element mounted on the device.

The device of FIG. 1b could also provide thermal switching or function as a thermal diode. As the temperature of the heat source rises 111 and a gap is formed, the amount of heat transfer from the bottom to the top of the device would change. Thermal switching has applications in regulating temperature of stoves, ovens, solar water heaters, and many others. In addition, thermal switching of this type has been proposed to function as a thermal diode to increase the efficiency of traditional thermoelectric devices by disengaging the cold side before the heat from the hot side is able to back flow to the cold side. See “Efficient Switched Thermoelectric Refrigerators for Cold Storage Applications”, b Ghoshal and Guha, Journal of Electronic Materials, Vol. 38, No. 7, 2009.

FIG. 2a shows one process for making the chip pair illustrated in FIG. 1. Because the nanometer gap feature of this invention permits the use of other semiconductor materials such as silicon, germanium, and silicon-germanium, and because these semiconductors are readily available in the form of circular wafers, the process of FIG. 2a shows how such wafers may be used as the materials for the thermoelectric layer 103 in FIG. 1. A further objective of the process of FIG. 2a is to employ standard equipment and processing that is readily available in the semiconductor and micro-electrical-mechanical systems (MEMs) industries.

Substrate wafer 201 in FIG. 2a provides the material for chip substrates 100 in FIG. 1, and this wafer is heavily doped to 0.001 ohm-cm resistivity for low electrical resistance. Another wafer 203 in FIG. 2a provides the material for thermoelectric layer 103 in FIG. 1. If it is desirable for the thermoelectric material to be a material different from the wafer 203 material, then in this case, a crystalline layer 202 may be grown as an epitaxial (EPI) layer on wafer 203 which then becomes a carrier wafer. Without limitation the EPI layer, may be a crystalline Silicon Germanium layer, a crystalline Bismuth Telluride layer grown using metal-organic chemical vapor deposition (MOCVD), or other crystalline layer that can be grown on substrate wafer 201. Whichever material 202 or 203 becomes the thermoelectric layer may be doped optimally for both resistivity and type (n or p) as needed. Interior metals 204 and 205 are deposited onto surfaces of the two wafers 201 and 203 in FIG. 2a for the purpose illustrated by layer 102 in FIG. 1. These metal layers 204 and 205 also have their surfaces coated with a final layer that facilitates metal-to-metal wafer bonding of wafer 201 to wafer 203. This metal coating could be gold in order to achieve the gold-to-gold compression bond common in the MEMs industry. Or, the metal coating could be gold-indium or other alloy in order to achieve a eutectic bond that is also common in the industry. Without limitation, other metal-to-metal wafer bonding techniques are also possible. Once wafers 201 and 203 are bonded together by the interior metals, then the outer surface of wafer 203 is ground down to the desired thickness to become a suitable thermoelectric layer down to the EPI layer. Because the gap-facing surfaces must be smooth for this invention, the outer surface of wafer 203 is also polished to atomic level smoothness. Now, the thermoelectric layer is prepared and underlying metals are present. Dicing streets 207 are patterned and etched in order to define individual dies and provide a path for wafer saw cutting. Etching the silicon with reactive ion etching and then etching the metals with wet or dry processing as defined by photolithography, for example, may fabricate these dicing streets 207. Without limitation, other methods may be used to accomplish the dicing streets 207. Once the gap-facing side of the wafer is prepared, then the backside metals 210 are deposited and aligned dicing streets 208 are patterned and etched. These backside metals 210 in FIG. 2a are deposited at an elevated temperature to achieve the wafer 211 with the curved bimetal dies. Similarly, the backside metals may be deposited at room temperature to achieve the wafer 212 that produces the flat dies. Finally, the separators 209 are deposited as silicon dioxide or other material, without limitation, on the corners of each die on wafer 212. These wafers 211 and 212 are then sliced to produce die pairs illustrated in FIG. 2b, which may then be deployed as illustrated in FIG. 1.

The gap facing surfaces of wafers 211 and 212 in FIG. 2a or of the equivalent dies sliced from these wafers may need some surface treatments in order to function effectively in the manner described for this invention. For example, if the thermoelectric layer is silicon or silicon-germanium, these materials oxidize very quickly when exposed to air. However, depositing a passivation layer, such as 5 nm of gold, will prevent this undesirable oxidation. A very thin metal layer is not expected to affect the thermoelectric performance of the device when the thickness is much less than the mean free path of electrons traveling through the material. Another passivation layer is accomplished by exposing the surface to hydrogen fluoride liquid or vapor, which serves to remove any oxide that is present and then provides a monolayer of hydrogen atoms that prevent re-oxidation for a period of time that allows for the chip pairs to be sealed in a vacuum chamber. In some cases, it may be desireable to use a passivation layer with a similar carrier concentration as the underlying Silicon or Silicon Germanium layer but also preventing oxides and other surface reactions. A thin 5 nm layer of Bismuth Telluride types of alloys or similar material has a desired carrier concentration and also is known to resist surface reactions. Without limitation, other passivation layers may be used.

FIG. 3a shows a similar process flow for the case where a thermoelectric layer is deposited, annealed to become crystalline, and then polished to remove any roughness introduced during the annealing. In this process, the thermoelectric layer is formed on metal surfaces. Deposited Bismuth Telluride is known to become rough when annealed because poly-crystals form in multiple orientations, some protruding up from the surface. See “The thermoelectric properties and crystallography of Bi—Sb—Te—Se thin films grown by ion beam sputtering”, by H. Noro, K. Sato, and H. Kagechika, Journal of Applied Physics, 73(3) 1 Feb. 1993.

A silicon wafer is again used as a substrate for the process illustrated in FIG. 3a. The gap-side film stack 302 is deposited and may include, without limitation, metal layers and adhesion layers such as titanium and a final thermoelectric layer 303. Without limitation, the thermoelectric layer may be bismuth, tellurium, antimony, selenium, lead, or any combination of these, or any other semiconductor material known to have desirable thermoelectric properties, possibly including those with high thermal conductivity. The entire wafer is then annealed by placing into a heated chamber, preferably with an inert gas, and heat-treating for many hours. The heat treatment temperature for telluride alloys typically is between 200 and 300 degrees centigrade. The heat treatment causes the film to change form from amorphous to polycrystalline and also causes the surface of layer 303 to become rough. The next step in the process is to polish thermoelectric side of the wafer using chemical-mechanical planarization (CMP). Once the surface is smooth, the dicing streets 304 may be patterned and etched. The resulting wafer with these gap side films may now be used to produce either a curved bimetal structure or a flat structure with silicon dioxide separators. The bimetal dies will be cut from wafer 307 wherein the backside metals are deposited at an elevated temperature. The flat dies will be cut from wafer 308 wherein the backside metals are deposited at room temperature and the silicon dioxide separators are deposited on the corners of each die. The bimetal wafer 307 is then sliced to produce the upper dies in FIG. 3b. The flat wafer 308 is then sliced to produce the lower dies in FIG. 3b. Surface treatments may be necessary to prevent oxidation. The chips from FIG. 3B may then be deployed as illustrated in FIG. 1.

FIGS. 4a and 4b illustrate how the chip pairs of FIGS. 1a, 1b, 2b, or 3b may be housed in a small vacuum package. Lids 401 provide the top and bottom and are made of a material that is thermal expansion matched, as needed, to the wall 407. Electricity and heat flow through the top and bottom and hence the lids 401 are preferably composed of a metal. The wall 407 separates the hot and cold sides and hence is preferably composed of silicon dioxide, or glass. If the metal used for lids 401 is Kovar, then the lids and glass will have similar thermal expansion coefficients and prevent temperature gradients and thermal cycling from breaking the package. Copper spreaders 403 connect the chips 405 and 406 to the lids 401 electrically and thermally. Solder, metallic adhesive, or other suitable connecting material 402, without limitation, connects the chips and lids together. Vacuum seal material 406 seals the metal and glass with a vacuum-tight seal, and may be composed of glass frit, gold indium, or other suitable material without limitation. Once fully assembled, the packaged chip pair is illustrated in FIG. 4b.

As mentioned, the chip pair of FIGS. 1a, 1b, 2b, and 3b, require some attracting force pushing them together so that contact occurs in the center and the bimetal forces of the curved die can work against this force to form a gap in the center. The attracting force may be provided by the vacuum pressure of the packaged device of FIG. 4b wherein the lids deform inward slightly to provide the force. Although this approach provides the needed force for some cases, an independent force mechanism may be required for other cases. For example, vacuum forces change with atmospheric pressure and elevation. Also, some uses of the device like ultra-sensitive cameras may prefer to have this device inside of another vacuum chamber in which case no attracting force will be available. For those cases where a separate, independent spring force is desired or required, FIGS. 5a-5c shows three different types of springs that might be used. In addition to providing the appropriate attracting force, the spring must also meet requirements for electrical conduction and thermal conduction. The preferred material is copper or silver because these metals have the highest conduction, both electrical and thermal. Other materials, such as aluminum, may be used if cost tradeoffs need to be made. Without limitation, the spring could be made of other metals or alloys of metals. In the example springs of FIGS. 5a-5c, the copper spreader 403 in FIG. 4a is mounted in the center of the spring with solder or silver adhesive, and the perimeter of the spring is attached to the lid again with solder or silver adhesive. In other embodiments, the spring could substitute for the copper spreader. Spring example 501 in FIG. 5a has one corrugation and many radial slits to increase compliance while maximizing the area through which the heat can flow. Spring example 502 of FIG. 5b is a similar design without the corrugation, and is easier to fabricate because vertical formation is not required. Spring example 503 of FIG. 5c has spiral slits, which increase compliance further. Without limitation, many other spring designs and materials might be suitable for this invention.

FIGS. 6a-6c show how an array 603 of the device of FIG. 4b may be assembled simultaneously and connected electrically to facilitate mass production and customization. An array of lids 401 are connected together with tabs 601. An array of glass tubes is affixed to the array of bottom lids. Then, the other items illustrated in FIG. 4a, including the copper spreaders, chip pairs, and adhesives are stacked inside the glass tubes using a pick-and-place robotic machine common to the electronic assembly industry. Then, an array of top lids is sealed to the glass tubes in a vacuum chamber. Once removed from the vacuum chamber, each package retains vacuum pressure inside. The size and shape of this array may be selected to match the diameter of a silicon wafer so that standard vacuum wafer-bonding machines may be employed, such as those manufactured by SUSS Microtec. Cutting the tabs 601 along cut lines 602 may then easily cut smaller arrays of a custom size 604 from the large array 603. The end result is a smaller array 604 wherein all top and bottom lids are electrically connected by the tabs to their neighboring lids. Finally, the tabs that are not needed for the series electrical connection of individual devices are cut, and wires 606 and 607 are attached to first and last electrical connection to produce the end product 605 that meets the requirements of a particular product specification or of a particular customer.

The packaging methods in FIGS. 4a-4b and 6a-6c require a separate vacuum package for each die pair. Such assembly involves many operations and handling of many small parts. Another package, as illustrated in FIGS. 7a-7b, allows for multiple chip pairs to be housed in one vacuum enclosure. Circuit boards 701 and 704, made of a vacuum compatible material such as aluminum oxide or aluminum nitride have copper-clad traces 706 that series connect chip pairs 404 and 405 together electrically. End connections 705 are brought to the exterior of the package for connection to a power supply for cooling or to an electrical load for power generation. A glass frame 702 separates the two sides and provides thermal isolation through the width of the frame. The sealing material between the top 701 and bottom 704 circuit boards and the glass frame 702 may again be glass frit, gold-indium or other suitable sealant that is vacuum compatible.

A packaging method requiring even less parts handling is shown in FIGS. 8a-8b. Here, the silicon wafers 801 and 802 become the tops and bottoms of the individual packages 803 and 804 in FIG. 8b. The glass wall 807 in FIG. 8a of the vacuum package is now deposited along with the glass separators and other features on the gap side of the wafer. Here, the glass wall is a horizontal member, but is bonded to the upper substrate again using glass frit or similar sealant 805. Sacrificial layer 808 is deposited prior to the glass wall layer 807 in order to provide sufficient rigidity of wafers 801 and 802 to endure slicing of chips in the wafer saw. Once wafers 801 and 802 are bonded together along vacuum bond lines 805 then and entire array of packaged die pairs may be sliced to yield the structure shown in FIG. 8b. These individual packages may be handled and assembled similar to the bismuth telluride pellets used in the industry today. Another advantage of this approach is that the various die pairs may be separated and grouped based on performance or defectiveness. The approach of FIGS. 7a-7b requires compromised performance or total discard if one of the die pairs is defective.

A chip pair was fabricated according to the dimensions and specifications of FIG. 3b. This chip pair was then mounted in a bell jar vacuum chamber between two spring-loaded electrodes. The vacuum pressure was 0.05 mTorr. A voltage was applied, and this voltage was gradually increased. A small thermocouple was mounted to each chip as well to measure the temperature of each electrode. From the two temperatures, the voltage, and the current readings, the industry standard figure of merit ZT was calculated. A higher ZT corresponds to higher efficiency. Two graphs of ZT vs. flex side temperature are shown in FIGS. 9a-9b. FIG. 9a shows ZT measured for a p-type device and FIG. 9b shows ZT measured for an n-type device. Clearly, the ZT is increasing as the higher temperature of the flexing chip produces a gap. For the p-type device of FIG. 9a, the p-type behavior of the thermoelectric layer was eventually degraded by the n-type behavior of the nanometer vacuum gap, as the dominant behavior of the device shifts from thermoelectric to thermo-tunneling.

Another pair of chips was fabricated according to the dimensions and specifications of FIG. 3b with the exception that a layer of gold was substituted for the thermoelectric layer. This chip pair was then mounted in a bell jar vacuum chamber between two spring-loaded electrodes. A voltage was applied, and this voltage was gradually increased. FIG. 10 shows a graph of the current flow vs. the applied voltage (IV-curve) for this chip pair. The current increases until a gap forms, and then the gap becomes a barrier for the electron flow, increasing resistance, and leveling out the IV curve. The shape of the IV curve is similar to current limiting and reset-able fuse devices like the Polyswitch family of devices manufactured by Tyco Electronics. Hence, the gap forming apparatus of this invention can be employed to build such devices.

Because low voltage and high current characterize thermoelectric junctions, most thermoelectric modules internally connect the junctions in series. By having many series connected junctions, the available supply or load voltage can better match a sum of individual junction voltages. These series connections mean that the heat must flow with the current in the p-type junctions and against the current in the n-type junctions.

It should be emphasized that the above-described embodiments of the present device and process, particularly, and “preferred” embodiments, are merely possible examples of implementations and merely set forth for a clear understanding of the principles of the invention. Many different embodiments of the tunneling and self-positioning electrode device described herein may be designed and/or fabricated without departing from the spirit and scope of the invention. All such modifications and variations are intended to be included herein within the scope of this disclosure and protected by the following claims. Therefore the scope of the invention is not intended to be limited except as indicated in the appended claims.

1. A device comprising first and second electrodes or electrode assemblies having facing surfaces wherein (1) the first electrode or electrode assembly has a curved surface and a mechanism to alter its curvature, (2) a center portion of said curved surface is initially in contact with the facing surface of the other electrode, and (3) the mechanism to alter curvature causes the contact to be removed and replaces it with a gap.

2. The device of claim 1, wherein the gap distance is less than 1.0 nanometers permitting barrier-free electron tunneling from a surface with a high work function.

3. The device of claim 1, wherein the gap distance is between 1.0 and 10.0 nanometers permitting electron thermo-tunneling from an electrode surface with a low work function.

4. The device of claim 2, wherein the gap distance varies with temperature thereby limiting the current flow across the gap to a safe level.

5. The device of claim 4, wherein the temperature is determined by internal heating of one or both electrodes from its current or voltage or current and voltage, thereby operating as a current limiter or reset-able fuse.

6. The device of claim 4, wherein the temperature is determined by an external source of heat and the gap opens or limits power delivered to that source, thereby operating as an over-temperature sensor or protector or circuit breaker.

7. The device of claim 4, wherein the temperature is determined by an external source of heat and the gap is open at one set of temperatures and closed at another set of temperatures, thereby operating as a relay.

8. The device of claim 1, wherein the gap distance is between 1.0 and 200 nanometers permitting photon tunneling.

9. The device of claim 2, wherein a semiconductor material is deposited on the facing surfaces of the electrodes.

10. The device of claim 9, wherein the semiconductor material comprises a thermoelectric material.

11. The device of claim 10, wherein the thermoelectric material is formed of a material selected from the group consisting of: bismuth telluride, antimony bismuth telluride, lead telluride, silicon germanium, thallium, a clathrate, a chalcogenide, and a superlattice of alternating layers.

12. The device of claim 3, wherein the low work function surface is selected from the group consisting of: Cesium, Barium, Strontium and an oxide of any of these.

13. The device of claim 8, wherein one of the electrodes is photosensitive and the other is photo-emissive.

14. The device of claim 13, wherein the photosensitive material is a photovoltaic material.

15. The device of claim 14, wherein the photosensitive material is selected from the group consisting of silicon, germanium, tellurium, cadmium and a combination or mixture thereof.

16. The device of claim 13, wherein the photo-emissive material is selected from tungsten, titanium, and a mixture thereof.

17. The device of claim 1, wherein the curved surface is formed by bonding two layers together having differing coefficients of thermal expansion at a temperature different from the planned operating temperature.

18. The device of claim 17, wherein one layer is a single crystal semiconductor and the other is a metal or metal alloy.

19. The device of claim 17, wherein one layer is a low-thermal-expansion metal alloy and the other is a high-thermal-expansion metal or metal alloy.

20. The device of claim 18, wherein the semiconductor is selected from the group consisting of silicon, germanium, silicon carbide, and gallium arsenide.

21. The device of claim 17, including separators outside the tunneling and contact areas for supporting the two electrodes.

22. The device of claim 21, wherein the separators are formed of glass or other material of low thermal conductivity.

23. The device of claim 21, wherein the separators support the two electrodes at one elevated temperature, eliminating the contact but allowing for tunneling, and eliminates all electron flow at another elevated temperature.

24. The device of claim 17, wherein the separators are deposited with or without a lubricating layer such as diamond like carbon.

25. The device of claim 4, wherein the separators are deposited on the metallic facing surfaces.

26. The device of claim 23, wherein the first elevated temperature is produced by Peltier-effect heat transfer, electrical resistance, photon absorption, or a combination thereof.

27. The device of claim 23, wherein the elevated temperature is produced by heat conduction in the contact area prior to its elimination, said heat originating from a heat source producing electricity from the Seebeck effect, thermo-tunneling effect, thermo-photovoltaic effect, or from an over-temperature environment.

28. The device of claim 1, wherein the pair of electrodes is contained within a vacuum enclosure.

29. The device of claim 28, wherein the vacuum enclosure includes a glass tube as a wall and two metal lids, and one electrode is connected electrically and thermally to each lid.

30. The device of claim 28, further including a spring to provide a preload force pushing the first electrode against the second electrode.

31. A plurality of devices of claim 28, made with two arrays of lids, one for the top and the other for the bottom of the enclosure, wherein a lid in each array is electrically connected to its neighbors.

32. The device of claim 31, wherein some of the electrical connections are later removed to achieve a desired set of electrical connections.

33. The device of claim 32, wherein the remaining electrical connections result in a series connection of individual devices to facilitate thermoelectric aggregation.

34. A plurality of devices as claimed in claim 1, wherein one set of electrodes is layered on a common substrate and the corresponding facing electrodes are layered on another common substrate.

35. The device of claim 2, wherein the semiconductor layer is achieved by bonding two wafers together and then thinning and smoothing one wafer to become the semiconductor layer.

36. The device of claim 35, wherein the wafers are bonded by one of compression bonding, anodic bonding, or eutectic bonding.

37. The device of claim 35, wherein an epitaxial layer is grown on one wafer, and then the thinning and smoothing removes all but the grown layer.

38. The device of claim 37, wherein the epitaxial layer is silicon-germanium doped for either n or p type thermoelectric operation.

39. The device of claim 1, wherein the surface is treated for passivation.

40. The device of claim 39, wherein the passivation is a thin layer of gold, platinum, or a hydrogen monolayer.

41. The device of claim 40, wherein the hydrogen monolayer is formed from exposure to hydrogen fluoride.

42. The device of claim 35, wherein one wafer or the epitaxial layer is Silicon, or a crystalline alloy of Bismuth, Antimony, Tellurium, Selenium, Lead, Indium Arsenic, Zinc, Germanium, Silver or any combination of these.

43. The device of claim 39, wherein the passivation layer is a thin deposited thermoelectric film.

44. The device of claim 43, wherein the passivating thermoelectric film is comprised of Bismuth, Tellurium, Antimony, Selenium, or any combination of these.

45. The device of claim 44, wherein the thin thermoelectric film is annealed.

46. The device of claim 9, wherein the thermoelectric layer is deposited on a wafer and then the wafer is annealed and polished.

47. The device of claim 34, wherein the resulting deposited, thinned, and epitaxial layers or any combination of these are patterned and etched with perpendicular lines to facilitate cutting of the wafer into individual chips.

48. The device of claim 34, wherein the separators are formed on the deposited, thinned, or epitaxial semiconductor layers or the passivation layer.

49. The device of claim 48, wherein the separators are formed from glass.

50. The device of claim 49, wherein the glass is Silicon Dioxide deposited and then patterned by photolithography or other methods.

51. The device of claim 26, in a vacuum enclosure.

52. The device of claim 34, including a frame wherein one substrate is bonded and sealed to the inner perimeter of the frame and the facing substrate is bonded and sealed to the outer perimeter of the frame.

53. The device of claim 52, wherein the frame is formed of a material with low thermal conductivity.

54. The device of claim 53, wherein the frame material is formed of glass or glass frit.

55. The device of claim 54, wherein the glass or glass-frit composition is altered with impurities to match its thermal expansion coefficient with that of the substrate material.

56. The device of claim 28, wherein the bonding and sealing takes place in a vacuum chamber, leaving the interior of the device evacuated when removed from the chamber.

57. The device of claim 56, wherein the glass frame and the vacuum seal are one in the same and are deposited on one of the substrates.

58. The device of claim 57, including a sacrificial layer that is later removed to reduce thermal conduction between the two electrodes.

59. The device of claim 58, wherein a deposited glass frame is formed on each pair of electrodes.

60. The device of claim 56, wherein the bonding and sealing material is glass frit.

61. The device of claim 56, wherein the bonding and sealing is anodic.

62. The device of claim 56, wherein the bonding and sealing is formed by compression.

63. The device of claim 29, including a getter.

64. The device of claim 63, wherein the getter is selected from the group consisting of: Titanium, Cesium, Barium, Potassium, Sodium and a combination of two or more thereof.

65. A process for converting heat to electrical energy comprising subjecting the device of claim 1 to a temperature difference.

66. The process of claim 65, wherein the heat source is selected from a radiation source, heat from the environment, geothermal energy, and heat generated from engines or from animal metabolism.

67. The process of claim 66, wherein the source of heat is a living human body.

68. The process of claim 67, wherein the source of heat is a living human body and the device is a hand held device.

69. The process of claim 65, wherein the source of heat is selected from an electrical, steam or internal combustion engine, burning fuel, or their exhaust gases.

70. The process of claim 69, wherein the source of heat is selected from an internal combustion engine or its exhaust gases and the device is incorporated in the engine or gas exhaust line as a heat sink.

71. The process of claim 65, operated at naturally occurring temperatures.

72. The process of claim 65, wherein the device is used in a refrigerator, an air conditioner, a cooling blanket, cooling clothing, electronics cooler, or a cooling device in contact with or contained within a human or animal body.

73. A device comprising multiple units of the device of claim 1, wherein the electrodes are arranged in multiple layers of periodic spacing.

74. A device comprising multiple units of the device of claim 1, assembled in series.

75. A device comprising multiple units of the device of claim. 1, assembled in parallel.

76. The device of claim 3, wherein the gap distance varies with temperature thereby limiting the current flow across the gap to a safe level.

77. The device of claim 76, wherein the temperature is determined by internal heating of one or both electrodes from its current or voltage or current and voltage, thereby operating as a current limiter or reset-able fuse.

78. The device of claim 76, wherein the temperature is determined by an external source of heat and the gap opens or limits power delivered to that source, thereby operating as an over-temperature sensor or protector or circuit breaker.

79. The device of claim 76, wherein the temperature is determined by an external source of heat and the gap is open at one set of temperatures and closed at another set of temperatures, thereby operating as a relay.

80. The device of claim 3, wherein a semiconductor material is deposited on the facing surfaces of the electrodes.

81. The device of claim 80, wherein the semiconductor material comprises a thermoelectric material.

82. The device of claim 81, wherein the thermoelectric material is formed of a material selected from the group consisting of: bismuth telluride, antimony bismuth telluride, lead telluride, silicon germanium, thallium, a clathrate, a chalcogenide, and a superlattice of alternating layers.

83. The device of claim 8, wherein a semiconductor material is deposited on the facing surfaces of the electrodes.

84. The device of claim 83, wherein the semiconductor material comprises a thermoelectric material.

85. The device of claim 84, wherein the thermoelectric material is formed of a material selected from the group consisting of: bismuth telluride, antimony bismuth telluride, lead telluride, silicon germanium, thallium, a clathrate, a chalcogenide, and a superlattice of alternating layers.

86. The device of claim 76, wherein the separators are deposited on the metallic facing surfaces.

87. The device of claim 17, wherein the separators are deposited on the metallic facing surfaces.

88. The device of claim 3, wherein the semiconductor layer is achieved by bonding two wafers together and then thinning and smoothing one wafer to become the semiconductor layer.

89. The device of claim 88, wherein the wafers are bonded by one of compression bonding, anodic bonding, or eutectic bonding.

90. The device of claim 88, wherein an epitaxial layer is grown on one wafer, and then the thinning and smoothing removes all but the grown layer.

91. The device of claim 8, wherein the semiconductor layer is achieved by bonding two wafers together and then thinning and smoothing one wafer to become the semiconductor layer.

92. The device of claim 91, wherein the wafers are bonded by one of compression bonding, anodic bonding, or eutectic bonding.

93. The device of claim 91, wherein an epitaxial layer is grown on one wafer, and then the thinning and smoothing removes all but the grown layer.

94. A process for converting heat to electrical energy comprising subjecting the device of claim 31 to a temperature difference.

95. A device comprising multiple units of the device of claim 31, wherein the electrodes are arranged in multiple layers of periodic spacing.

96. A device comprising multiple units of the device of claim 31, assembled in series.

97. A device comprising multiple units of the device of claim 31, assembled in parallel.

98. A process for converting heat to electrical energy comprising subjecting the device of claim 34 to a temperature difference.

99. A device comprising multiple units of the device of claim 34, wherein the electrodes are arranged in multiple layers of periodic spacing.

100. A device comprising multiple units of the device of claim 34, assembled in series.

101. A device comprising multiple units of the device of claim 34, assembled in parallel.
